(19) United States
(12) Patent Application Publication
(10) Pub. No.: US 2026/0175545 A1
(43) Pub. Date: Jun. 25, 2026

(54) COMPOSITE SUBSTRATE AND CIRCUIT BOARD

(71) Applicants: GUANGZHOU FANGBANG ELECTRONICS CO., LTD, Guangdong (CN); ZHUHAI DACHUANG ELECTRONICS CO., LTD., Guangdong (CN)

(72) Inventor: Zhi Su, Guangdong (CN)

(21) Appl. No.: 18/872,032

(22) PCT Filed: Jun. 6, 2023
(86) PCT No.: PCT/CN2023/098453

§ 371 Date: Dec. 5, 2024

(30) Foreign Application Priority Data
Apr. 24, 2023 (CN) 202310444627.5

(51) Int. Cl. B32B 27/08; B32B 27/32; B32B 27/40; H10W 20/00; H10W 70/65; H10W 70/68

(52) U.S. Cl. CPC B32B 27/08; B32B 27/32; B32B 27/40; H10W 20/033; H10W 70/65; H10W 70/682

(57) ABSTRACT

The present disclosure provides a composite substrate and a circuit board. The composite substrate includes a first resistive layer and a base layer, wherein the first resistive layer is stacked on a surface of at least one side of the base layer; and a surface of a side of the base layer facing the first resistive layer is provided with a plurality of protrusions, a roughness Ra of the surface of the side of the base layer provided with the protrusions is 0.5 μm-5 μm, and a quantity of the protrusions is 0.1*10³/mm-3*10³/mm. The above limitation improves uniformity of the first resistive layer deposited on the surface of the base layer, and further improves uniformity of square resistance of the first resistive layer, so as to facilitate manufacturing of an embedded resistor with high precision and facilitate performance of the circuit board and an electronic element.

### TECHNICAL FIELD

The present disclosure relates to the technical field of composite substrates, in particular to a composite substrate and a circuit board.

### BACKGROUND

With the rapid development of wireless communications and electronic apparatuses, the electronic apparatuses have been gradually evolving towards precision, miniaturization and thinness, which requires components inside the electronic apparatuses to be as miniature and thin as possible. Resistor elements inside electronic apparatuses evolved from plug-in resistors with pins to chip resistors, and then from the chip resistors to embedded resistors, gradually developing towards lightness and thinness. The application process of the embedded resistor is roughly as follows: a composite substrate is attached to a circuit board, and the embedded resistor is etched through an etching process. The composite substrate includes a base layer and a resistive layer located on a surface of a side of the base layer, and a surface of a side of the resistive layer away from the base layer is adapted to adhere to the circuit board.

However, the uniformity of square resistance of existing composite substrates is poor, which is not conducive to manufacturing of embedded resistors with high accuracy.

### SUMMARY

In view of the above, the present disclosure provides a composite substrate and a circuit board in order to solve the technical problem of how to improve the uniformity of square resistance of an embedded resistor.

The present disclosure provides a composite substrate, including a first resistive layer and a base layer, wherein the first resistive layer is stacked on a surface of at least one side of the base layer; and a surface of a side of the base layer facing the first resistive layer is provided with a plurality of protrusions, a roughness Ra of the surface of the side of the base layer provided with the protrusions is 0.5 μm-5 μm, and a quantity of the protrusions is 0.1*10³/mm-3*10³/mm.

In some embodiments, an axis of a top center of the protrusion of the base layer is a central axis of the protrusion, and a horizontal distance between central axes of adjacent protrusions is 1 μm-20 μm.

In some embodiments, the protrusions on the surface of the base layer are distributed as follows: a distance between central axes of adjacent protrusions is D, and a quantity proportion of protrusions with 2 μm≤D≤11 μm is greater than or equal to 70%.

In some embodiments, the protrusions on the surface of the base layer are distributed as follows: a quantity proportion of protrusions with 2 μm≤D<4 μm is 10%-40%, a quantity proportion of protrusions with 4 μm≤D<6 μm is 40%-70%, a quantity proportion of protrusions with 6 μm≤D<8 μm is 10%-40%, a quantity proportion of protrusions with 8 μm≤D<11 μm is 5%-20%, and a quantity proportion of protrusions with 2 μm≤D<11 μm is less than or equal to 100%.

In some embodiments, a thickness of the first resistive layer is 5 nm-3 μm.

In some embodiments, a material of the base layer is a conductive material or a dielectric material. The conductive material includes at least one of copper, aluminum, titanium, zinc, iron, nickel, chromium, cobalt, silver, and gold.

In some embodiments, the first resistive layer includes at least one element of Ni, Cr, Si, P, N, Ti, Pt, Ta, Mo, Sn, and O.

In some embodiments, a material of the first resistive layer includes at least one of NiCrSi, NiCrAlSi, NiP, AlN, NiCr, TiN, Pt, Cr, Cr—SiO, Cr—Si, Ti—Si, Ti—W, TaN, Mo, and Ni—Sn.

In some embodiments, the composite substrate includes a film layer located on a surface of a side of the first resistive layer away from the base layer.

In some embodiments, a thickness of the film layer is 0.5 μm-100 μm.

In some embodiments, a conductive layer is arranged on a side of the film layer away from the first resistive layer.

In some embodiments, the conductive layer is a single-layer conductive layer or a multi-layer conductive layer.

In some embodiment, a second resistive layer is arranged between the film layer and the conductive layer.

In some embodiments, the first resistive layer is formed by one or multiple processes selected from electroplating, electroless plating, physical vapor deposition, and chemical vapor deposition.

The present disclosure further provides a circuit board which includes the above composite substrate.

The technical solution of the present disclosure has the following advantages:

According to the composite substrate and the circuit board provided in the present disclosure, uniformity of the first resistive layer deposited on the surface of the base layer is improved by controlling the roughness of the surface of the base layer and the quantity of the protrusions, and uniformity of square resistance is further improved. Moreover, a resistor manufactured through the method is applied to a circuit substrate, has a better bonding effect, and improves structural stability of an electronic apparatus.

### BRIEF DESCRIPTION OF THE DRAWINGS

In order to more clearly illustrate technical solutions in the embodiments of the present disclosure or in the prior art, a brief introduction to the accompanying drawings required for the description of the embodiments or the prior art will be provided below. Apparently, the accompanying drawings in the following description are some of the embodiments of the present disclosure, and those of ordinary skill in the art would also be able to derive other drawings from these drawings without making creative efforts.

FIG. 1 is a schematic structural diagram of a longitudinal section of a composite substrate according to an example of the present disclosure;

FIG. 2 is a scanning electron microscope (SEM) photograph of a base layer of FIG. 1;

FIG. 3 is an SEM photograph of a longitudinal section of a composite substrate according to an example of the present disclosure;

FIG. 4 is a schematic diagram of a stacking relation of another composite substrate according to an example of the present disclosure;

FIG. 5 is a schematic diagram of a stacking relation of another composite substrate according to an example of the present disclosure; and

FIG. 6 is a schematic diagram of a stacking relation of another composite substrate according to an example of the present disclosure.

### REFERENCE NUMERALS

1—base layer; 11—protrusion; 2—first resistive layer; 3—film layer; 4—conductive layer; and 5—second resistive layer.

### DETAILED DESCRIPTION OF THE EMBODIMENTS

The technical solutions of the present disclosure will be described below clearly and comprehensively in conjunction with the drawings. Apparently, the examples described are merely some examples rather than all examples of the present disclosure. Based on the examples of the present disclosure, all other examples acquired by those of ordinary skill in the art without making creative efforts fall within the scope of protection of the present disclosure.

In the description of the present disclosure, it is to be noted that the terms “upper”, “lower”, “inner”, “outer”, etc. indicate azimuthal or positional relations based on those shown in the drawings only for ease of description of the present disclosure and for simplicity of description, and are not intended to indicate or imply that the referenced device or element must have a particular orientation and be constructed and operated in a particular orientation, and thus cannot be construed as a limitation on the present disclosure.

It should be understood that in order to improve peeling strength of a composite substrate and a circuit board and improve difficulty of separating them, a base layer is typically treated to form a plurality of protrusions on a surface of a side of the base layer, such that the surface of the side of the base layer has a certain roughness, and then a resistive layer deposited on the rough surface of the base layer has a rough surface correspondingly.

The applicant found that too many or too few protrusions on the surface of the base layer and too high or too low roughness of the base layer both will lead to poor deposition uniformity of the resistive layer, thereby leading to poor uniformity of square resistance of the resistive layer. Uniformity of square resistance of an existing composite film is about ±10%, which is not conducive to manufacturing of an embedded resistor with high precision and influences performance of a circuit board and even an electronic element. Particularly, too many protrusions are likely to cause more areas where a resistance material cannot be deposited between adjacent protrusions, thus resulting in poor deposition uniformity of the resistive layer. However, too few protrusions will cause less peeling strength of the composite substrate and the circuit board, such that the composite substrate cannot be stably fixed on the circuit board.

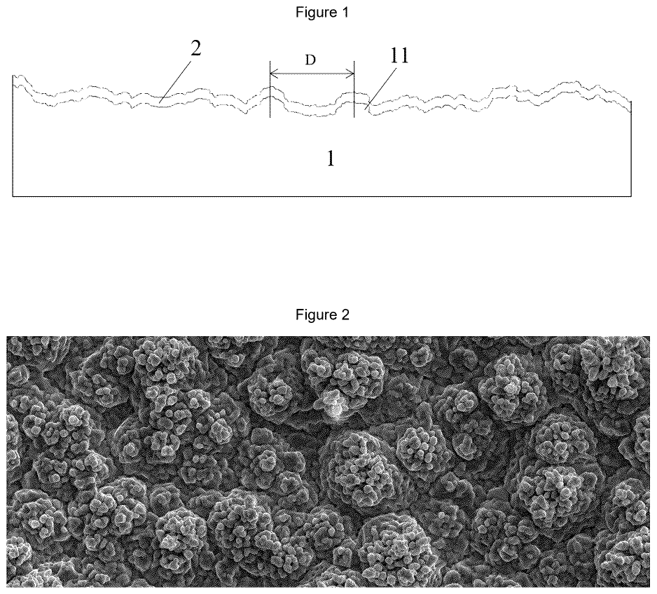

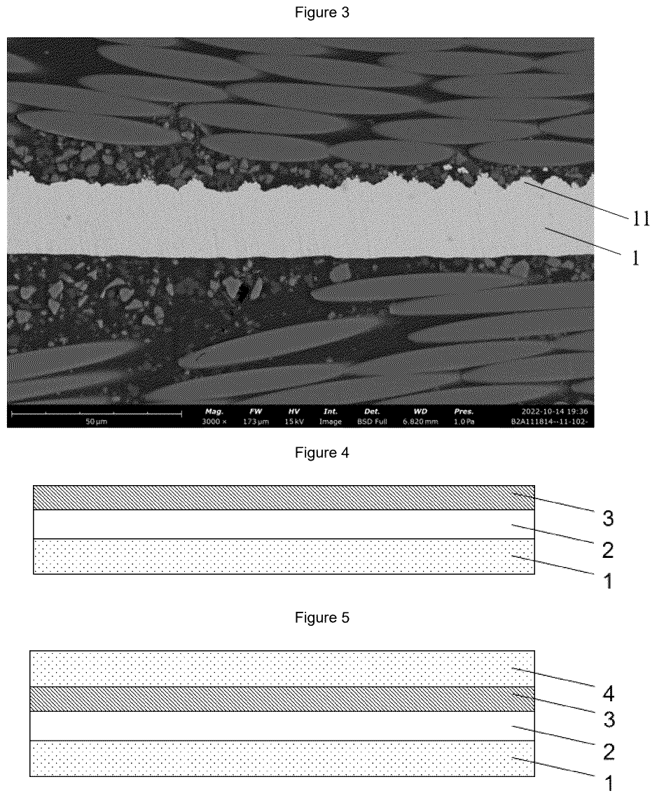

In view of this, with reference to FIGS. 1 and 3, an example provides a composite substrate, including:

a base layer 1, wherein a surface of at least one side of the base layer 1 is provided with a plurality of protrusions 11 closely arranged, a roughness Ra of the surface of the side of the base layer 1 provided with the protrusions 11 is 0.5 μm-5 μm, a quantity of the protrusions 11 is 0.1*10³/mm-3*10³/mm, and the roughness Ra of the surface of the side of the base layer 1 provided with the protrusions 11 may be preferably 0.5 μm-1.5 μm; and a first resistive layer 2, wherein the first resistive layer 2 is located on the surface of the side of the base layer 1 provided with the protrusions 11, the first resistive layer is very thin, and a shape of the first resistive layer is a shape of covering the base layer, and the shapes of the first resistive layer and the base layer are basically the same. The roughness of the base layer in the present disclosure is measured from a side of the first resistive layer away from the base layer. FIG. 2 is a scanning electron microscope (SEM) image of a kind of base layer. A magnification of FIG. 2 is 5000. In FIG. 3, the first resistive layer is deposited on the surface of the side of the base layer provided with the protrusions, but the first resistive layer is invisible in FIG. 3 because it is thin.

By limiting the quantity of the protrusions 11, the resistance material can be deposited as far as possible to the area between the adjacent protrusions 11. By limiting the roughness of the surface of the base layer 1, uniformity of the first resistive layer 2 deposited on the surface of the base layer 1 is improved, and uniformity of square resistance of the first resistive layer 2 is further improved. The uniformity of square resistance is within a range of ±5%, which is beneficial to manufacturing of the embedded resistor with high precision and performance of the circuit board and even the electronic element. Furthermore, the first resistive layer 2 and the base layer 1 are arranged in the same shape, that is, the surface of the first resistive layer 2 also has protrusions 11 correspondingly. The quantity of the protrusions 11 also guarantees that the composite substrate and the circuit board have appropriate peeling strength, so as to guarantee that the composite substrate can be stably fixed on the circuit board and is less likely to be peeled from the circuit board, thereby improving structural stability of an electronic apparatus.

Preferably, the quantity of the protrusions 11 is 0.1*10³/mm-2*10³/mm. For example, the quantity of the protrusions 11 may be 0.1*10³/mm, 0.5*10³/mm, 1*10³/mm, 1.5*10³/mm, 2*10³/mm, or a range formed by a combination of any of the above numbers.

Further, an axis perpendicular to the base layer 1 and passing through a top center of the protrusion 11 is a central axis of the protrusion 11, and a horizontal distance between central axes of adjacent protrusions 11 is 1 μm-20 μm. For example, the horizontal distance between the central axes of adjacent protrusions 11 may be 1 μm, 2 μm, 3 μm, 4 μm, 5 μm, 6 μm, 7 μm, 8 μm, 9 μm, 10 μm, 20 μm, or a range formed by a combination of any of the above numbers. Preferably, a distance between the central axes of adjacent protrusions 11 is 1 μm-11 μm. It is proved by long-term experiments that the uniformity of square resistance is better when the distance is in the above range.

Further, the protrusions on the surface of the base layer are distributed as follows: a distance between central axes of adjacent protrusions is D, and a quantity proportion of protrusions with 2 μm≤D≤11 μm is greater than or equal to 70%. The distribution reduces surface defects of the base layer, such that defects of the first resistive layer deposited on the surface of the base layer are further reduced, the thickness of the first resistive layer is more uniform, and the uniformity of square resistance of the finally manufactured first resistive layer is better.

In order to make the square resistance of the first resistive layer more uniform, the protrusions on the surface of the base layer are distributed as follows: a quantity proportion of protrusions with 2 μm≤D<4 μm is 10%-40% (for example, 17%), a quantity proportion of protrusions with 4 μm≤D<6 μm is 40%-70% (for example, 55%), a quantity proportion of protrusions with 6 μm≤D<8 μm is 10%-40% (for example, 19%), a quantity proportion of protrusions with 8 μm≤D≤11 μm is 5%-20% (for example, 9%), and the quantity proportion of protrusions with 2 μm≤D≤11 μm is 100%. Wherein, the uniformity of square resistance of a resistor manufactured with the distance between the central axes and the quantity proportion within the above ranges is further improved.

It should be noted that the term “proportion” in this example refers to a ratio of the quantity of protrusions satisfying a certain condition to the total quantity of protrusions in at least part of the surface of the base layer. For example, “a quantity proportion of protrusions with 2 μmsD<4 μm is 10%-40%” may mean that the ratio of the quantity of protrusions satisfying 2 μmsD<4 μm on the entire surface of the base layer to the total quantity of protrusions on the entire surface of the base layer is 10%-40%, and may also mean that the ratio of the quantity of protrusions satisfying 2 μm≤D<4 μm in a partial area of the surface of the base layer to the total quantity of protrusions in the area is 10%-40%.

In the example, a thickness of the first resistive layer 2 is 5 nm-3 μm. Preferably, the thickness of the first resistive layer 2 is 5 nm-200 nm. Since the first resistive layer 2 is thin, a shape of the first resistive layer 2 is substantially consistent with a shape of the surface of the side of the base layer having the protrusions 11, that is, the first resistive layer 2 and the base layer 1 are configured in the same shape. Specifically, the surface of the first resistive layer 2 also has protrusions 11, which correspond to the protrusions 11 in the base layer and have substantially the same size. For example, the thickness of the base layer 1 may be 2 μm, 4 μm, 6 μm, 8 μm, 10 μm, 12 μm, 14 μm, 16 μm or 18 μm, and the thickness of the first resistive layer 2 may be 10 nm, 25 nm, 50 nm, 75 nm, 100 nm, 125 nm, 150 nm, 175 nm or 200 nm.

In the example, a material of the base layer is a conductive material or a dielectric material. The base layer may be of a single-layer structure or a structure formed by stacking a plurality of layers. The conductive material includes, but is not limited to, at least one of copper, aluminum, titanium, zinc, iron, nickel, chromium, cobalt, silver, and gold. Specifically, the base layer may be copper foil, aluminum foil, titanium foil, zinc foil, iron foil, nickel foil, chromium foil, cobalt foil, silver foil, or gold foil, may also be an alloy foil containing at least two of copper, aluminum, titanium, zinc, iron, nickel, chromium, cobalt, silver, and gold, and may also be a composite substrate formed by combining at least two of copper foil, aluminum foil, titanium foil, zinc foil, iron foil, nickel foil, chromium foil, cobalt foil, silver foil, and gold foil. The dielectric material includes, but is not limited to, polyethylene terephthalate (PET), polypropylene (PP), polystyrene (PS), an Ajinomoto build-up film (ABF), bismaleimide triazine (BT) resin, polyacrylic acid, polyurethane, polyimide, etc. In a base layer having a multi-layer structure, the materials of different layers may be the same or different.

The first resistive layer is a key functional layer of the composite substrate, and is used for implementing a resistance function of an embedded resistor. The first resistive layer may be made from different materials according to requirements of different functions, so as to have different resistance characteristics. Specifically, the material of the first resistive layer includes at least one element of Ni, Cr, Si, P, N, Ti, Pt, Ta, Mo, Sn, and O. Specifically, the material may be at least one of NiCrSi, NiCrAlSi, NiP, NiCr, AlN, TIN, Pt, Cr, Cr—SiO, Cr—Si, Ti—Si, Ti—W, TaN, Mo, and Ni—Sn. The first resistive layer may be of a single-layer structure or a structure formed by stacking a plurality of layers. In the first resistive layer having the multi-layer structure, the materials of different layers may be the same or different.

In this example, the first resistive layer is formed by at least one of electroplating, electroless plating, physical vapor deposition, and chemical vapor deposition. The square resistance of the first resistive layer is 1 Ω-2000 Ω.

It should be noted that the thickness of the base layer, the thickness and a maximum width of the first resistive layer and other related parameters in this example are obtained by manufacturing a composite substrate sample into slices and then measuring the slices by a scanning electron microscope. A magnification of the scanning electron microscope is 2000-70000.

With reference to FIG. 4, as an alternative embodiment, the composite substrate further includes a film layer 3 located on a surface of a side of the first resistive layer 2 away from the base layer 1. On one hand, the film layer can protect the first resistive layer 2, such that the first resistive layer 2 is prevented from being damaged by external force. On the other hand, when the composite substrate is attached to the circuit board, the film layer can bond the first resistive layer 2 and the circuit board, such that the peeling strength of the composite substrate and the circuit board is further improved, the composite substrate is less likely to be peeled from the circuit board, and structural stability of the electronic apparatus is improved. Furthermore, after the film layer is arranged, a foil-clad board can be manufacture and directly applied to a hard printed circuit board (PCB) or a flexible PCB.

Specifically, a thickness of the film layer is 0.5 μm-100 μm. For example, the thickness of the film layer may be 2 μm, 5 μm, 7 μm, 10 μm, 12 μm, 15 μm, 20 μm, 30 μm, 40 μm, 55 μm, 60 μm, 70 μm, 80 μm, 90 μm or 100 μm. The film layer is selected from at least one of polystyrene thermoplastic resin, vinyl acetate thermoplastic resin, polyester thermoplastic resin, polyethylene thermoplastic resin, polyamide thermoplastic resin, rubber thermoplastic resin, acrylate thermoplastic resin, phenolic thermosetting resin, epoxy thermosetting resin, thermoplastic polyimide thermosetting resin, carbamate thermosetting resin, melamine thermosetting resin, alkyd thermosetting resin, and ABF resin. For example, the film layer is selected from at least one of modified epoxy resin, modified acrylic resin, polyethylene terephthalate, polybutylene terephthalate, polyethylene, polyethylene naphthalate, polyphenylene, polyvinyl chloride, polysulfone, polyphenylene sulfide, polyetheretherketone, polyphenylene oxide, polytetrafluoroethylene, liquid crystal polymer, polyethylenimine, epoxy glass cloth, and BT resin. A specific thickness and material of the film layer may be selected and set by those skilled in the art according to actual needs.

Further, with reference to FIG. 5, in an example, on the basis of the film layer 3 arranged in the composite substrate, a conductive layer 4 is arranged on a side of the film layer 3 away from the first resistive layer 2, so as to form a foil-clad board containing the first resistive layer. The foil-clad board is of a four-layer structure and can be directly applied to a hard board or a flexible board. Specifically, the conductive layer may be of a single-layer structure or a structure formed by stacking a plurality of layers. That is, the conductive layer may be copper foil, aluminum foil, titanium foil, zinc foil, iron foil, nickel foil, chromium foil, cobalt foil, silver foil, or gold foil, may also be an alloy foil containing at least two of copper, aluminum, titanium, zinc, iron, nickel, chromium, cobalt, silver, and gold, and may also be a composite substrate formed by combining at least two of copper foil, aluminum foil, titanium foil, zinc foil, iron foil, nickel foil, chromium foil, cobalt foil, silver foil, and gold foil. The material of the conductive layer may be the same as the material of the base layer or different, and those skilled in the art may set the material according to actual needs.

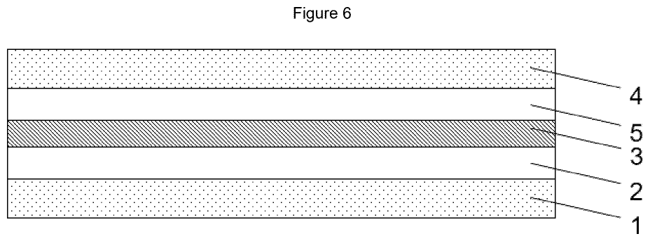

Further, with reference to FIG. 6, in an example, a second resistive layer 5 is arranged between the film layer 3 and the conductive layer 4, to form an asymmetric structure. Wherein, the material of the second resistive layer may be the same as the material of the first resistive layer 2 or different, and those skilled in the art may set the material according to actual needs. In this example, the second resistive layer is formed by at least one of electroplating, electroless plating, physical vapor deposition, and chemical vapor deposition.

It should be noted that the protrusions in this example are formed by stacking fine grains. With reference to FIG. 1, a height of the protrusions is higher than a lowest surface of the conductive layer.

This example further provides a circuit board which includes the above composite substrate. The circuit board has all the advantages of the above composite substrate, which will not be described in detail herein.

Specific examples and comparative examples are now provided illustratively to support the technical effects of the technical solutions of the disclosure. Wherein, the composite substrate in the examples and the comparative examples all include a base layer and a first resistive layer. A surface of a side of the base layer is provided with a plurality of protrusions, and the first resistive layer is stacked on the surface of the side of the base layer provided with the protrusions. The base layer is a copper foil with a thickness of 18 μm, a material of the first resistive layer is NiCr alloy, and a thickness of the first resistive layer is 22 nm.

### Example 1

In this example, the roughness Ra of the surface of the side of the base layer having the protrusions is 0.8 μm. The quantity of protrusions is 1.0*10³/mm. The distance between central axes of adjacent protrusions is D. The protrusions on the surface of the base layer are distributed as follows: the quantity proportion of protrusions with 2 μmsD<4 μm is 10%, the quantity proportion of protrusions with 4 μm≤D<6 μm is 50%, the quantity proportion of protrusions with 6 μm≤D<8 μm is 30%, and the quantity proportion of protrusions with 8 μm≤D<11 μm is 10%.

### Example 2

The composite substrate provided in this example differs from the composite substrate provided in Example 1 only in that in the composite substrate provided in this example, the quantity of protrusions is 0.1*10³/mm.

### Example 3

The composite substrate provided in this example differs from the composite substrate provided in Example 1 only in that in the composite substrate provided in this example, the quantity of protrusions is 3.0*10³/mm.

### Example 4

In this example, the roughness Ra of the surface of the side of the base layer having the protrusions is 0.8 μm. The quantity of protrusions is 0.1*10³/mm. The distance between central axes of adjacent protrusions is D. The quantity proportion of protrusions with 2 μm≤D≤11 μm is 70%. Specifically, the protrusions on the surface of the base layer are distributed as follows: the quantity proportion of protrusions with 2 μm≤D<4 μm is 10%, the quantity proportion of protrusions with 4 μm≤D<6 μm is 40%, the quantity proportion of protrusions with 6 μm≤D<8 μm is 10%, and the quantity proportion of protrusions with 8 μm≤D<11 μm is 10%.

### Example 5

In this example, the roughness Ra of the surface of the side of the base layer having the protrusions is 0.8 μm. The quantity of protrusions is 0.1*10³/mm. The distance between central axes of adjacent protrusions is D. The protrusions on the surface of the base layer are distributed as follows: the quantity proportion of protrusions with 2 μmsD<4 μm is 10%, the quantity proportion of protrusions with 4 μm≤D<6 μm is 40%, the quantity proportion of protrusions with 6 μm≤D<8 μm is 40%, and the quantity proportion of protrusions with 8 μm≤D<11 μm is 10%.

### Example 6

In this example, the roughness Ra of the surface of the side of the base layer having the protrusions is 0.8 μm. The quantity of protrusions is 0.1*10³/mm. The distance between central axes of adjacent protrusions is D. The protrusions on the surface of the base layer are distributed as follows: the quantity proportion of protrusions with 2 μmsD<4 μm is 40%, the quantity proportion of protrusions with 4 μm≤D<6 μm is 45%, the quantity proportion of protrusions with 6 μm≤D<8 μm is 10%, and the quantity proportion of protrusions with 8 μm≤D<11 μm is 5%.

### Example 7

In this example, the roughness Ra of the surface of the side of the base layer having the protrusions is 0.8 μm. The quantity of protrusions is 0.1*10³/mm. The distance between central axes of adjacent protrusions is D. The protrusions on the surface of the base layer are distributed as follows: the quantity proportion of protrusions with 2 μm≤D<4 μm is 20%, the quantity proportion of protrusions with 4 μm≤D<6 μm is 50%, the quantity proportion of protrusions with 6 μm≤D<8 μm is 10%, and the quantity proportion of protrusions with 8 μm≤D<11 μm is 20%.

### Example 8

In this example, the roughness Ra of the surface of the side of the base layer having the protrusions is 0.8 μm. The quantity of protrusions is 0.1*10³/mm. The distance between central axes of adjacent protrusions is D. The protrusions on the surface of the base layer are distributed as follows: the quantity proportion of protrusions with 2 μmsD<4 μm is 10%, the quantity proportion of protrusions with 4 μm≤D<6 μm is 70%, the quantity proportion of protrusions with 6 μm≤D<8 μm is 15%, and the quantity proportion of protrusions with 8 μm≤D<11 μm is 5%.

### Comparative Example 1

The composite substrate provided in this comparative example differs from the composite substrate provided in Example 1 only in that in the composite substrate provided in this comparative example, the roughness Ra of the surface of the side of the base layer provided with the protrusions is 6 μm.

### Comparative Example 2

The composite substrate provided in this comparative example differs from the composite substrate provided in Example 1 only in that in the composite substrate provided in this comparative example, the quantity of protrusions is 4.0*10³/mm.

### Comparative Example 3

The composite substrate provided in this comparative example differs from the composite substrate provided in Example 1 only in that in the composite substrate provided in this comparative example, the quantity of protrusions is 0.05*10³/mm.

### Test Example

The composite substrates provided in Examples 1-8 and Comparative Examples 1-3 are subjected to a square resistance uniformity test and a peel force test. Wherein, in the square resistance uniformity test process, firstly, square resistances M at different positions of the composite substrate are tested, square resistance test points are uniformly distributed on the surface of the composite substrate, and the number of square resistance test points is 20. Then average square resistances Mₐᵥₑ at different positions of the composite substrate are calculated, and a maximum square resistance Mₘₐₓ and a minimum square resistance Mₘᵢₙ are selected. Then an upper limit value of uniformity of square resistance and a lower limit value of uniformity of square resistance are calculated: the upper limit value of uniformity f square resistance=(Mₘₐₓ−Mₐᵥₑ)/Mₐᵥₑ*100%; and the lower limit value of uniformity of square resistance=(Mₘᵢₙ−Mₐᵥₑ)/Mₐᵥₑ*100%. Test results are shown in Table 1.

TABLE 1

| | Uniformity of square | Uniformity of square |
|---|---|---|
| | resistance (upper | resistance (lower |
| | limit value) | limit value) |
| Example 1 | 4.30% | −4.50% |
| Example 2 | 4.50% | −4.30% |
| Example 3 | 4.50% | −4.80% |
| Example 4 | 4.80% | −4.60% |
| Example 5 | 4.00% | −3.90% |
| Example 6 | 3.90% | −3.60% |
| Example 7 | 3.60% | −3.70% |
| Example 8 | 2.60% | −2.80% |
| Comparative example 1 | 10.20% | −10.00% |
| Comparative example 2 | 11.70% | −11.30% |
| Comparative example 3 | 9.10% | −9.90% |

It can be seen that the technical solution in the examples achieves more outstanding uniformity of square resistance and more stable performance.

Apparently, the above examples are merely instances made for clarity of illustration instead of limiting the embodiments. It will be apparent to those of ordinary skill in the art that other changes or variations in different forms may be made in light of the above description. Not all embodiments need be and can be exhaustive herein. Apparent changes or variations derived therefrom are still within the scope of protection created by the present disclosure.

1. A composite substrate, comprising a first resistive layer and a base layer, wherein the first resistive layer is stacked on a surface of at least one side of the base layer; and a surface of a side of the base layer facing the first resistive layer is provided with a plurality of protrusions, a roughness Ra of the surface of the side of the base layer provided with the protrusions is 0.5 μm-5 μm, and a quantity of the protrusions is 0.1*10³/mm-3*10³/mm.

2. The composite substrate according to claim 1, wherein an axis of a top center of the protrusion of the base layer is a central axis of the protrusion, and a horizontal distance between central axes of adjacent protrusions is 1 μm-20 μm.

3. The composite substrate according to claim 1, wherein the protrusions on the surface of the base layer are distributed as follows: a distance between central axes of adjacent protrusions is D, and a quantity proportion of protrusions with 2 μm≤D≤11 μm is greater than or equal to 70%.

4. The composite substrate according to claim 3, wherein the protrusions on the surface of the base layer are distributed as follows: a quantity proportion of protrusions with 2 μm≤D<4 μm is 10%-40%, a quantity proportion of protrusions with 4 μm≤D<6 μm is 40%-70%, a quantity proportion of protrusions with 6 μm≤D<8 μm is 10%-40%, a quantity proportion of protrusions with 8 μm≤D≤11 μm is 5%-20%, and a quantity proportion of protrusions with 2 μm≤DE≤11 μm is less than or equal to 100%.

5. The composite substrate according to claim 1, wherein a thickness of the first resistive layer is 5 nm-3 μm.

6. The composite substrate according to claim 1, wherein a material of the base layer is a conductive material or a dielectric material.

7. The composite substrate according to claim 1, wherein the composite substrate comprises a film layer located on a surface of a side of the first resistive layer away from the base layer.

8. The composite substrate according to claim 7, wherein a thickness of the film layer is 0.5 μm-100 μm.

9. The composite substrate according to claim 7, wherein a conductive layer is arranged on a side of the film layer away from the first resistive layer.

10. The composite substrate according to claim 9, wherein the conductive layer is a single-layer conductive layer or a multi-layer conductive layer.

11. The composite substrate according to claim 9, wherein a second resistive layer is arranged between the film layer and the conductive layer.

12. The composite substrate according to claim 1, wherein the first resistive layer is formed by one or multiple processes selected from electroplating, electroless plating, physical vapor deposition, and chemical vapor deposition.

13. A circuit board, comprising the composite substrate according to claim 1.

14. The circuit board according to claim 13, wherein an axis of a top center of the protrusion of the base layer is a central axis of the protrusion, and a horizontal distance between central axes of adjacent protrusions is 1 μm-20 μm.

15. The circuit board according to claim 13, wherein the protrusions on the surface of the base layer are distributed as follows: a distance between central axes of adjacent protrusions is D, and a quantity proportion of protrusions with 2 μm≤D≤11 μm is greater than or equal to 70%.

16. The circuit board according to claim 15, wherein the protrusions on the surface of the base layer are distributed as follows: a quantity proportion of protrusions with 2 μm≤D<4 μm is 10%-40%, a quantity proportion of protrusions with 4 μm≤D<6 μm is 40%-70%, a quantity proportion of protrusions with 6 μm≤D<8 μm is 10%-40%, a quantity proportion of protrusions with 8 μm≤D≤11 μm is 5%-20%, and a quantity proportion of protrusions with 2 μm≤D≤11 μm is less than or equal to 100%.

17. The circuit board according to claim 13, wherein a thickness of the first resistive layer is 5 nm-3 μm.

18. The circuit board according to claim 13, wherein a material of the base layer is a conductive material or a dielectric material.

19. The circuit board according to claim 13, wherein the composite substrate comprises a film layer located on a surface of a side of the first resistive layer away from the base layer.

20. The circuit board according to claim 19, wherein a thickness of the film layer is 0.5 μm-100 μm.
